(19) United States
(12) Patent Application Publication
(10) Pub. No.: US 2008/0042185 A1
(43) Pub. Date: Feb. 21, 2008

(54) EEPROM MEMORY ARRAY HAVING 5F2 CELLS

(75) Inventor: Bohumil Lojek, Colorado Springs, CO (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/464,670

(22) Filed: Aug. 15, 2006

(51) Int. Cl. H01L 29/788

(52) U.S. Cl. 257/315

(57) ABSTRACT

A non-volatile memory array featuring cells with split gate transistors and an overall area extent of 5F2, i.e. five times the minimum lithographic feature size squared. While smaller calls are known, the cells of the present invention each have a select device and a floating gate transistor with adjacent cells having shared source-drain lines, all controlled by only four lines including two bit lines, a word line and a select gate line. The lines are extended beyond the boundary of the array where electrical contact is made for random access reading, programming and erasing, i.e. a contactless array.

### TECHNICAL FIELD

The invention relates to semiconductor memory and, in particular, to non-volatile electrically erasable and programmable memory arrays made by lithography characterized by a minimum feature size.

### BACKGROUND ART

Among the smallest semiconductor non-volatile memory cells that have been made to date by photomicrography are those involving the minimum feature size that can be resolved by photolithographic equipment, a dimension commonly designated as “F”. As a specific dimension, F depends on lithographic equipment, but is scalable to whatever lithographic equipment is available. In modern stepper equipment, for example manufactured by Canon, Nikon or ASML, F is typically in the range of 50 to 150 nanometers and is forecast to become smaller, F depends upon the wavelength of the exposing light multiplied by a resolution factor and divided by the numerical aperture of the lithographic system. The resolution factor depends on several variables in the photolithographic process including the quality of the potoresist used and resolution enhancement techniques such as phase shift masks, off-axis illumination and optical proximity correction. In any event, F is a characteristic of particular semiconductor manufacturing equipment that uses photolithography.

Memory calls having an area, in top view on a wafer, of four and five times the square of the minimum lithographic features size, known as 4F2 and 5F2 cells, respectively, are among the smallest memories reported. In this application, the designation 4F2 means an area for a memory cell of four times the minimum feature size squared, while the designation 5F2 means an area for a memory cell of five times the minimum feature size squared. Note that in the present application, the relevant area for a cell is not merely for a memory transistor, but for a memory device and a select device.

A prior art example of a 4F2 transistor is U.S. Pat. No. 7,075,146, entitled “4F2 EEPROM NROM Memory Arrays with Vertical Devices” by L. Forbes. Another example is U.S. Pat. No. 7,061,801 entitled “Contactless Bidirectional Nonvolatile Memory”, also illustrating 4F2 devices. While some smaller calls have been built, manufacturing complexity has increased. Even among 4F2 devices, many involve vertical transistors that have moderate manufacturing complexity.

Of particular interest in memory arrays, particularly NOR arrays, are non-volatile memory cells that consist of a select transistor as well as a memory transistor wherein each cell can be addressed for programming, erasing and reading. A select transistor allows for such individual cell addressing. A particularly useful and compact non-volatile memory transistor is a triple poly, split gage memory device as shown in U.S. Pat. No. 6,111,788 to C. Chen et al. Such a device has a channel that is partly controlled by a select gate and partly controlled by a floating gate. Normally, such devices cannot be 4F2 devices because the space taken by two gates would preclude a minimum size geometry.

An object of the invention was to devise a memory cell having a select transistor as well as a non-volatile memory transistor in an array where each memory cell is very compact having dimensions approaching 4F2 devices.

### SUMMARY OF INVENTION

The invention is a 5F2 non-volatile memory cell having a split gate transistor with both a select gate and a floating gate controlling a channel located between spaced apart source and drain regions. In particular, the cell has preferred lengthwise by widthwise dimensions of 5/2 F units by 2F units, respectively, with the channel having a preferred width of one F unit. The select gate is over a first portion of the channel while the floating gate is over a second portion of the channel and over the select gate. In the row of X-direction of the array, source-drain regions are shared with laterally adjacent memory cells. In the columnar direction or Y-direction small buffer regions provide the separation for parallel word lines relative to neighboring cells in the columnar direction in an X-Y array of identical cells. No subsurface isolation regions are used. In the row direction there is no separation between cells because the cells abut at shared source-drain regions. A control gate over the floating gate and both source-drain regions extends in the row or X-direction as a word line, while the source-drain regions as well as the select gate extend in the columnar or Y-direction as respective bit lines and a select line. Thus, four lines are available at the periphery of the array for contactless control of programming, reading and erasing the memory array.

### BRIEF DESCRIPTION OF THE DRAWINGS

FIG. 1 is a side sectional view of a non-volatile memory cell of the present invention.

FIG. 2 is a top view of a portion of a memory array using memory cells as sown in FIG. 1.

FIG. 3 is an electrical schematic of a portion of a memory array of the kind shown in FIG. 2.

FIG. 4 is an electrical schematic of a memory cell of the kind shown in FIG. 3.

FIG. 5 is a top view of the areawise extent of the memory cells in the memory array of FIG. 2, particularly illustrating 5F2 geometry.

FIGS. 6-11 are sequential sectional views illustrating principal manufacturing steps for the non-volatile memory cell of FIG. 1.

### BEST MODE OF CARRYING OUT THE INVENTION

With reference to FIG. 1, the non-volatile memory transistor cell 11 is shown to be built upon a P-type semiconductor substrate 13 that is preferably a wafer substrate. While the transistor cell could be built within a P-well isolation region, the present invention features a lack of isolation structures, including structures that normally define an active region. In transistor memories, a cell is defined as a data storage unit. In some memories, the cell is occupied by a single memory transistor while in other memories, where grater address selectively is needed, as in the present invention, the cell is occupied by a memory transistor and a select device. In the present invention, the combination of a memory transistor and select device is handled by a split gate memory transistor.

Source-drain 15 and source-drain 17 are shallow N+ implanted regions in substrate 13. The term “source-drain” is used for subsurface device electrodes because there is no distinction in construction between sources and drains and thus a source-drain electrode could be treated as either a source or as a drain without distinction. Implantation is by self-alignment, as described below. The implantation is along lines as explained below so that source-drain regions associated with transistors in the same column all form lines that extend form one region of a wafer to another distant region, emerging at a periphery of the memory. The source-drain lines will form bit lines for the array as described below. When the source-drain lines carry appropriate voltages, a conductive channel will be induced between spaced apart source-drain regions associated with a select gate and a floating gate working together as described below.

Spaced slightly above the channel, separated from the channel by a thin layer of gate oxide 19, is the conductive select gate 21, made as a linear stripe pattern of polysilicon parallel to the bit lines. In a manufacturing process, the elect gage fabrication layer is termed the “poly 1” layer. The channel, occupying a space between source-drain 17 and source-drain 15, is entirely in the substrate and is partly electrically controlled by select gage 21. Another portion of the channel is controlled by floating gate 25 that has a portion 26 laterally adjacent to select gate 21 at about the same elevation above the substrate and another portion 24 above the select gate 21.

In all instances, the floating gate 25, in particular the portion 26, is insulated from the select gate 21 with the TEOS spacer 23 providing lateral insulation and a nitride layer 28 providing insulation over the top of select gate 21. In the manufacturing process, the polysilicon gate fabrication layer is termed the “poly 2” layer because it is formed after the poly 1 layer. Note that the select gate 21 and the laterally adjacent floating gate portion 26 together can exert electrical control over the channel in two channel regions adjacent to each other. In other words, in order to have electrical communication of electrons, i.e. conduction, from source-drain electrode 17 to source-drain electrode 15, both of the adjacent channel regions must favor such communication with an appropriate positive electric field that favors electron migration from one source-drain electrode to the other source-drain. If one of the gates is negative or neutral such communication of electrons will tend not to occur.

A top oxide layer 30 extends up the side walls of the select gate 21 and floating gate 25 and across the top of the floating gate 25 and down the wall of floating gate portion 26 to join the gate oxide layer 19. A third poly later 27, poly 3, in the range of 1500 Å-2500 Å extends completely over the cell as a control gate and a word line. The function of the top oxide layer 30 is to provide insulation between the control poly layer 27 and the underlying floating gate 25. The control poly layer 27 is separated from substrate 13 by the gate oxide 19.

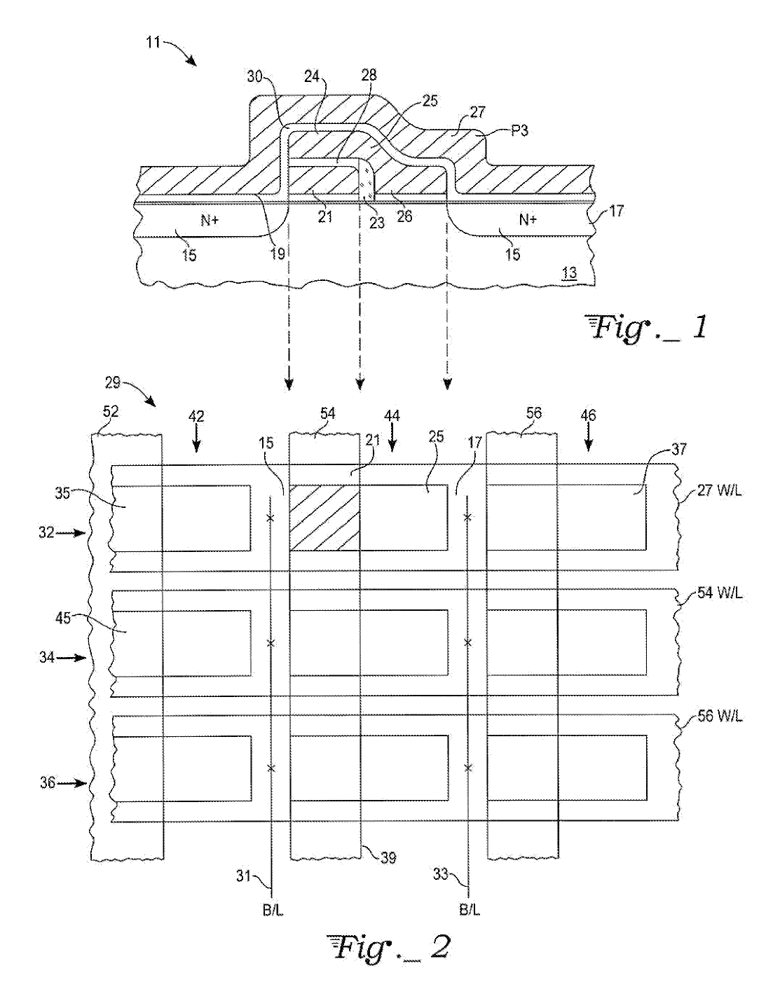

In the top view of FIG. 2, a portion 29 of a non-volatile memory is depicted in which the footprint of a memory array reveals in top view the cell of FIG. 1. The central portion of FIG. 1 is projected downwardly, as indicated by the dashed lines, onto FIG. 2. However, the sides of FIG. 1, apart from the central portion, are exaggerated in size relative to FIG. 2 for purposes of illustration.

The array of FIG. 2 has rows 32, 34, and 36, as well as columns 42, 44 and 46 running in X and Y directions respectively. In column 44, select gate 21 is shown as a vertical stripe, i.e. a select line 39 that extends beyond the array. Source-drain region 15 is seen to be shared with an adjacent cell in column 42, while source-drain region 17 is seen to be shared with an adjacent cell in column 46. Shared source-drain regions exist in rows 34 and 36, as well, directly below source-drain 15 and source-drain 17. The columnar extension of shared source-drain regions gives rise to subsurface bit lines 31 and 33, respectively.

Floating gate 25 is seen to be a rectangle in row 32, column 44. Adjacent floating gates are seen to be floating gate 35 in row 32, column 42 and floating gate 37 in row 32, column 46. The word line gate stripe 27 extends across row 32. Similar word line gate stripes 54 and 56 are seen extending across rows 34 and 36 respectively. Parallel word line stripes are space apart from each other to maintain insulative conduction. The select gate 21 is sen to be part of a vertical select gate stripe 54 perpendicular to the word line stripes. Other select gate stripes 52 and 56 are parallel to select gate stripe 54 but are associated with other columns of the memory array. In summary, cells are seen to be identical rectangular regions that are laterally adjacent to each other with shared buried source-drain lines. The cells are adjacent to each other in the vertical or columnar direction yet provide word line separation as described above. Each cell can be independently addressed by use of appropriate signals on a pair of neighboring bit lines, a word line and a select line. The lines, electrical counterparts of process stripes, are seen to extend beyond the cells to the periphery of the array where electrical contact may be made. Within the array, the array is contactless.

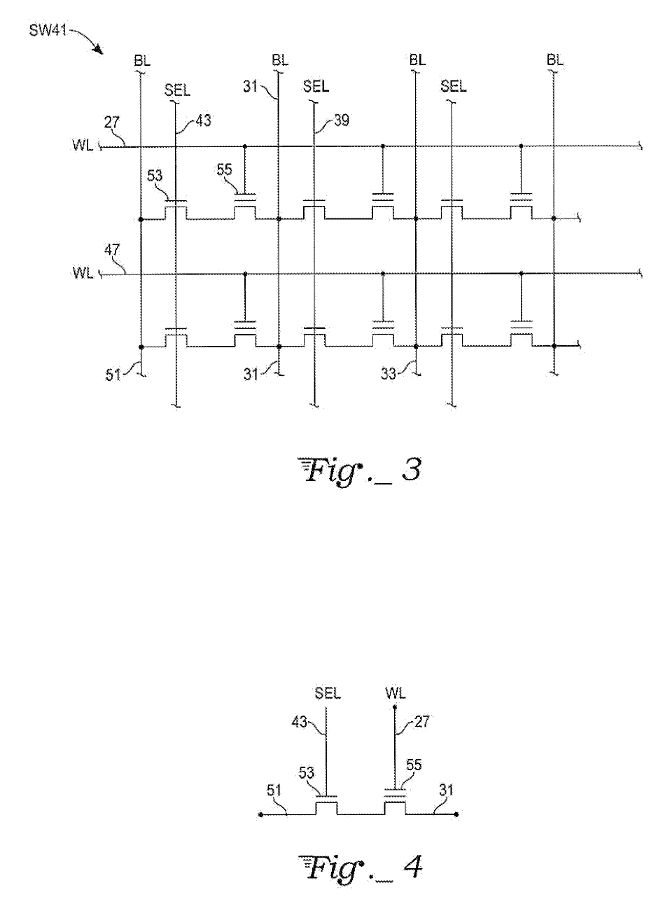

In FIG. 3 the array portion 41 corresponds to two rows of array portion 29 of FIG. 2. Word line 27 is associated with a cell having a bit line 51 being a source-drain electrode, a bit line 31 being another source-drain electrode, a select device 53 operated by select line 43 and non-volatile memory transistor 55. This cell has four electrical contacts, namely word line 27, bit lines 31 and 51 and select line 43. Every other cell has a unique combination of four corresponding electrodes. For example, the laterally adjacent cell in the same row is operated by bit lines 31 and 33, word line 27 and select line 39.

In FIG. 4, a single cell shown in FIG. 3 is separately shown with select device 53 connected in series by a common electrode with floating gate non-volatile memory transistor 55. The select device is controlled via a select line 43 while the non-volatile memory transistor 55 is controlled by word line 27. At the same time conduction through the devices is established from a first source-drain line 51 on one side of the cell to a second source-drain line 31 on the distant side of the cell. As mentioned above, the four lines 43, 27, 51 and 31 uniquely control and address this cell, particularly for reading in a NOR memory array, with the select device providing not only unique address selection capability, but also read disturb protection for the non-volatile memory transistor. If the select device were not present, voltages associated with adjacent cells could potentially affect charge stored on the memory transistor.

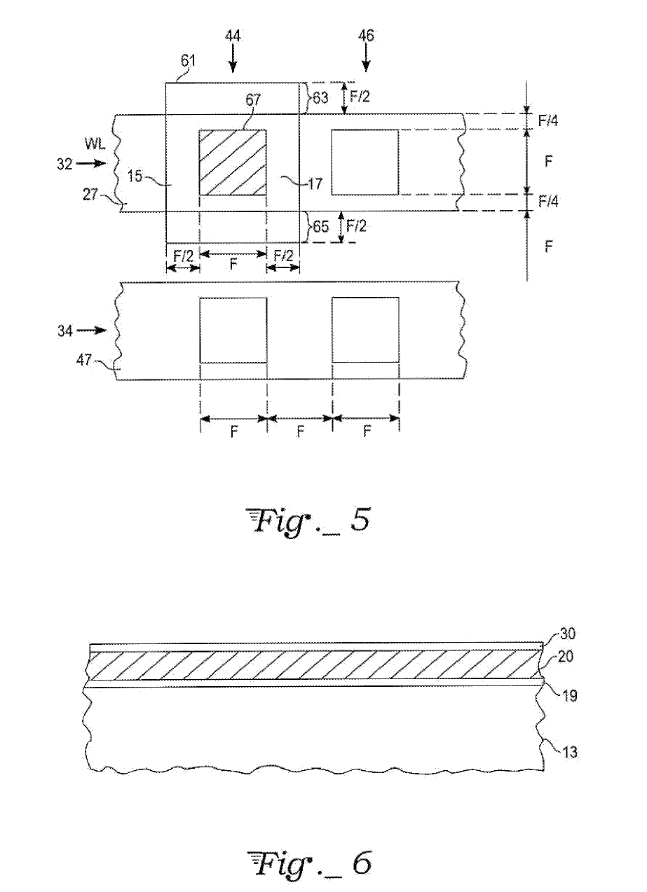

In FIG. 5 the form factor for memory cells is apparent in the top view plot of a cell at the intersection of row 32 and column 44. This cell has an imaginary boundary 61 which is not a material boundary but an areawise boundary of the cell footprint including border zones 63 and 65 that isolate word line 27 from adjacent word lines, such as adjacent word line 47 in row 34. The border zones are not isolation regions built with field oxide or trench isolation but merely spatial regions having a columnwise dimension of F/2 units for each of zones 63 and 65, where F is the minimum feature size discussed previously. The inner square 67 illustrated by hatched shading represents the intersection of the stacked select and floating gates that have further regions running in perpendicular directions, as seen by the corresponding hatched shading in FIG. 2, where the floating gate extends further in the row direction than the select gate and the select gate extends further in the columnar direction. The dimension of the inner square 67 is one F unit while the source-drain regions on either side of the inner square 67 have a dimension of F/2 units. The word line 27 extends over the inner square 67 with a slight amount of excess coverage in the columnar direction being F/4 units top and bottom. This means that the word line stripe 27 has a row width of 3/2 F units. Adding all dimensions, in the columnar direction the cell has a dimension of F/2+F/4+F+F/4+F/2 or a total of 5/2 F units. In the row direction the cell has dimensions of F/2+F+F/2 or a total of 2F units. Multiplying the row times the column dimension, or 5/2F by 2F, the total areawise dimension of the cell is 5F squared, or 5F2.

Construction of memory cells of the type illustrated in FIG. 1 is shown by the principal steps illustrated in FIGS. 6-11. In FIG. 6, the p-type substrate 13 is seen to have the layer of gate oxide 19 grown thereon. Above the gate oxide layer is the poly 1 layer 20 which will ultimately become the select gate. The thickness of the poly 1 layer is approximately 1000 Angstroms. Atop the poly 1 layer is a nitride layer 30, or ONO layer, having a thickness of approximately 300 Angstroms. As previously noted, as an alternative to a p-type substrate, a p-well might be employed in an n-type substrate. However, no isolation structures have been built and a p-type substrate is preferred.

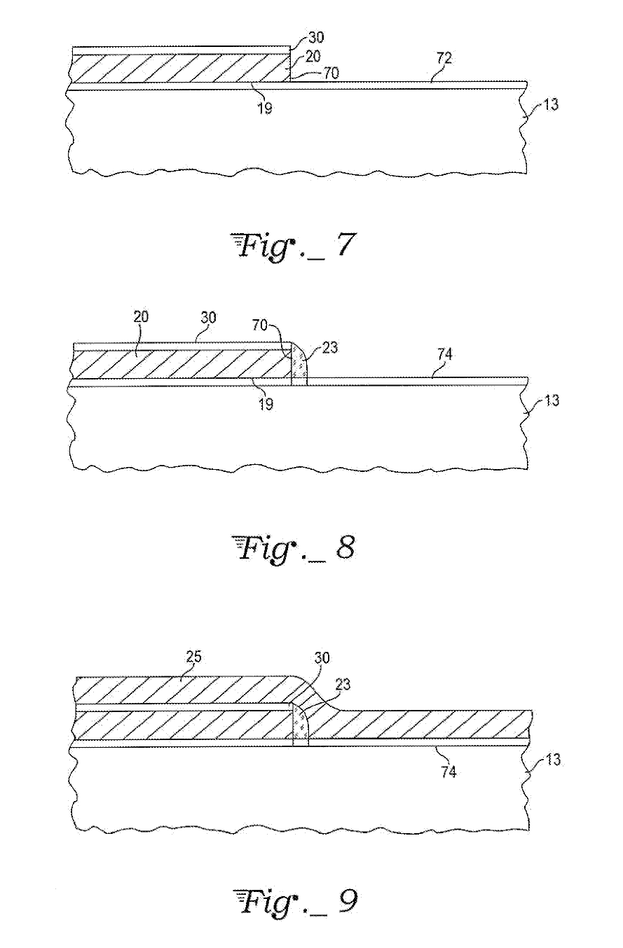

In FIG. 7, the layers 19, 20 and 30, shown in FIG. 6, have been etched relative to the substrate 13 and a vertical edge 70 has been formed. Reoxidation is applied over the substrate in region 72 to isolate the substrate from overlying structures. Next, a layer of TEOS is applied over the entire structure of FIG. 7 and then the TEOS is mainly etched away except for a small spacer 23 adjacent to edge 70. The with of the spacer is approximately 400 Angstroms. After etching, the region to the right of the spacer is reoxidized in region 74 to restore oxide over the substrate. Next, the floating polysilicon gate layer 25 is applied over the nitrode layer 30, as well as the TEOS spacer 23 and the reoxidized region 74. This is a second polysilicon layer or poly 2. The floating polysilicon gate layer has a thickness of approximately 500-1000 Angstroms.

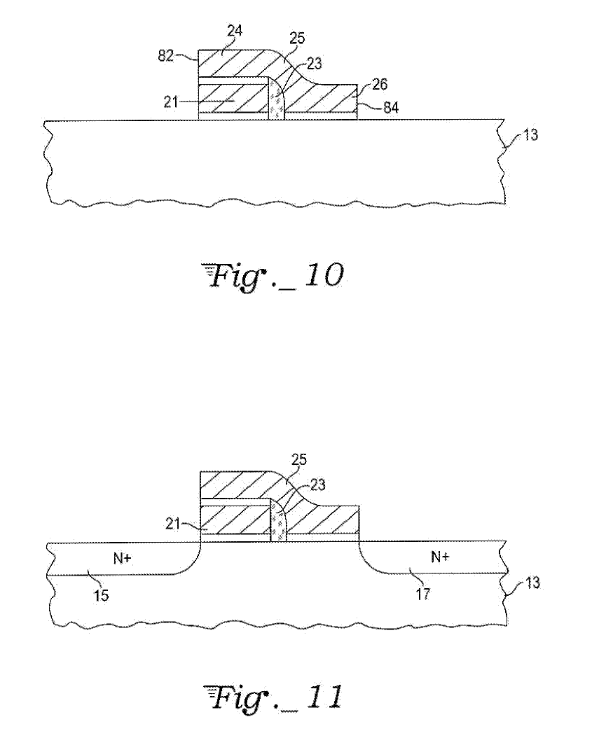

Next, masks are applied over the wafer to trim individual cells to a desired dimension and prepare for self-aligned implantation of source-drain electrodes. FIG. 10 shows an etched select gage 21 below a floating gate 25 with the floating gate having a first portion 24 directly over the select gate and a second portion 26 laterally adjacent to the select gate 21 and separated by the TEOS spacer 23. This is followed by a shallow ion implantation of source-drain regions 15 and 17, shown in FIG. 11. The etched edges 82 and 84 allows for self-aligned implantation of the two source-drain regions. This is followed by deposition of a top oxide layer 30, seen in FIG. 1, followed by the poly 3 word line top stripe 27, also seen in FIG. 1. All cells in the memory array are now complete, being formed in rows and columns as shown in FIG. 2.

1. A memory having a closely packed 5F2 array of rows and columns of non-volatile memory cells in a semiconductor substrate, the rows extending in a widthwise direction and the columns extending in a lenghtwise direction, each memory cell comprising,
a widthwise dimension equal to 2F units where one F unit is occupied by a split gate and two one-half F units are occupied by source and drain regions on opposite widthwise sides of the split gate, and
a lengthwise dimension of 5/2 F units where one F unit is occupied by the split gate and ¾ F units on opposite lengthwise sides of the split gage are occupied by buffer regions.

2. The memory of claim 1 wherein said split gage has a select gate under a portion of a floating gate.

3. The memory of claim 2 wherein the floating gate has a width dimension of one F unit.

4. The memory of claim 2 wherein a conductive wordline extends in the widthwise direction in insulated relation over the floating gate and over the source and drain regions.

5. The memory of claim 4 wherein the select gate, floating gate and conductive wordline are first, second and third layers of polysilicon, respectively.

6. The memory of claim 4 wherein the select gate, source, drain and workline are contactless electrodes for the memory array.

7. The memory of claim 1 wherein the source and drain are N-type semiconductor material with P-type material therebetween.

8. The memory of claim 4 wherein said wordline has opposite buffer region in the lenghtwise direction, each buffer region having a length of one-half F.

9. The memory of claim 6 wherein source and drain regions extend in the lengthwise direction from one cell to the next in shared relation with adjacent cells.

10. The memory of claim 1 wherein the select gate extends in the lengthwise direction continuously through a column of memory cells.

11. A memory having a closely packed 5F2 array of rows and columns of non-volatile memory cells in a semiconductor substrate, the rows extending in a widthwise direction and the columns extending in a lengthwise direction, each memory cell having a memory transistor comprising,
a semiconductor substrate with spaced apart source and drain regions with a channel therebetween, all contained within a boundary of lengthwise by widthwise dimensions of 5/2 F by 2F,
a select gate over a first portion of the channel,
a floating gate over a second portion of the channel and over the select gate,
a control gate over the following gate and the source and drain regions, the source and drain regions shared with memory transistors of adjacent cells.

12. The memory transistor of claim 11 further defined by the floating gate having a widthwise dimension not greater than F units.

13. The memory of claim 11 further defined by the select gate having a widthwise dimension at least one-half F units but less than F units.

14. The memory transistor of claim 11 wherein the source and drain regions extend as conductive lines in the lenghtwise direction.

15. The memory transistor of claim 11 wherein the select gate extends as a conductive line in the lenghtwise direction.

16. The memory transistor of claim 11 wherein the control gate extends as a conductive line in the widthwise direction.

17. The memory of claim 11 wherein the cells have conductive lines running through the array in lengthwise and widthwise directions as contactless electrodes for programming and erasing individual memory cells.

18. The memory of claim 17 wherein source and drain regions and the select gate are all conductive lines in the lengthwise direction and the control gate extends as a control line in the widthwise direction.

19. A method of making a non-volatile memory array using split gate transistors in memory cells controlled by four lines including two bit lines, a select line and a word line comprising,
arranging word lines to run in a first direction,
arranging select gate lines and bit lines to run in a second direction perpendicular to the first direction,
arranging memory cells having said word lines, select gate lines and bit lines in adjacent cells in an X-Y array, each cell having an area of 5F2.

20. The method of claim 19 further defined by making electrical contact with said word lines, bit lines and select gate lines beyond the boundary of the X-Y array of cells thereby providing a contactless memory.

21. The method of claim 19 further defined by arranging the memory cells with spacing between word lines, bit lines and select gate lines in a spatial arrangement without isolation structures.
